(19) United States
(12) Patent Application Publication
(10) Pub. No.: US 2016/0047404 A1
(43) Pub. Date: Feb. 18, 2016

(54) SPRING CLIP MOUNTING SYSTEM

(71) Applicant: STEREN ELECTRONICS INTERNATIONAL, LLC, San Diego, CA (US)

(72) Inventor: R. Brent HOWARD, San Diego, CA (US)

(73) Assignee: STEREN ELECTRONICS INTERNATIONAL, LLC, San Diego, CA (US)

(21) Appl. No.: 14/458,252

(22) Filed: Aug. 13, 2014

(51) Int. Cl. F16B 2/18; F16B 2/04; H05K 5/02; F16M 13/02

(52) U.S. Cl. CPC F16B 2/185; F16M 13/022; F16B 2/04; H05K 5/0204

(57) ABSTRACT

A spring clip mounting system that enables electronics to be mounted in a cavity, for example in a wall and includes at least one spring clip coupled to a mount. The at least one spring clip includes a body, a lever arm, a pole, a first spring element, a rectangle, and a second spring element. The body moves down the pole when the lever arm is asserted, and moves up the pole when the rectangle is asserted. The at least one spring clip is rotated to enable a portion of the mount and the at least one spring clip to be inserted into a cavity for example in a wall, to couple the mount to the wall when the lever arm is asserted. The rectangle is asserted and the system to be removed from the wall.

### BACKGROUND OF THE INVENTION

1. Field of the Invention

Embodiments of the invention generally relate to a spring clip mounting system including at least one spring clip and a mount that enable electronics to be rapidly and easily removably coupled or otherwise mounted in a cavity in a wall, floor or ceiling or other surface through manual operation of elements that make up the system, for example without requiring the use of tools such as a screwdriver, wrench or pliers.

2. Description of the Related Art

Generally, securing electronics to a wall, such as drywall, requires the use of a typical electronics assembly that is affixed within a cavity or recess in a wall, ceiling, floor or other surface. The electronics assembly generally includes the electronics, such as a speaker, light, camera, alarm, etc., and a mount to hold the electronics. Typically, installing and uninstalling the assembly requires multiple time-consuming steps and multiple tools. Often, a user typically requires the use of both hands to install the assembly, as well as a screwdriver or other tool, to secure and fasten the electronics in place. This usually occurs while the user is required to maintain balance on a ladder. For example, one hand is typically used to hold the assembly in place and a second hand is used to affix or remove the assembly via one or more tools, and fasteners such as screws or bolts simultaneously. Typical electronic assembly installations, removals and replacements may also include coupling and decoupling the electronics to and from a power source within the surface and hence may be dangerous. The installation process thus requires multiple time-consuming steps, which are generally cumbersome, and require the use of various tools.

For example, U.S. Pat. No. 5,867,583 to Hazelwood et al., entitled “Twist-Lock-Mountable Versatile Loudspeaker Mount”, appears to disclose a twist-lock installation and removal assembly for loudspeakers. According to Hazelwood et al., in a twist-lock embodiment, a plurality of elongated slots located at a rear side of the loudspeaker mounting flange engage a plurality of lock tabs of a panel to enable a twist-lock installation and removal of the assembly. Furthermore, Hazelwood et al. appears to disclose wherein a loudspeaker is mounted to the panel utilizing hardware means, such as screw, bolt or rivet fasteners.

U.S. Pat. No. 7,334,767 to Wright, entitled “Tool-Less Frame Fastening System”, appears to disclose a frame assembly for mounting recessed fixtures using a ratcheting fastener. According to Wright, the ratcheting fastener 114 is rotationally coupled to the frame 102 and manually secured by rotating the fastener 114, pushing the fastener 114 toward frame 102, and due to the main problem of threaded ratchets, namely that there may be a gap between teeth when the fastener is pressed to a wall, a lever 118 is then depressed into a receiver 120 to counter any gap. Operation of these components within a closed space requires knowledge of the locations of the components and operation of more than one component in order to securely fasten the mount to the wall. In addition, the ratchet post 116 is a fairly complex component which requires threaded areas with machined flat facets, a non-threaded end 132, a second end with an orthogonal hole 130 that has a shoulder and is thicker than end 132. In summary, this component is much more time consuming to form and machine than a simple post and has the disadvantage of discrete positions between the threads, thus requiring lever 118 to account for the gaps between the teeth. As discussed in Wright, the ratcheting fastener is released by first disengaging the lever 118 from the receiver 120 and then lifting the lever and then rotating the lever to disengage the fastener from the teeth on ratchet post 116. Thus, the device of Wright requires multiple time-consuming steps with different components that include discrete ratchets, levers that including lifting and rotating to engage and disengage the frame. The operation of the device and multiple components within the cavity to install and remove the apparatus is complicated in that the components lie within a cavity and require operation of multiple components in a particular order and generally without a direct view of the components that are inside of the apparatus when coupled to a wall.

For example, U.S. Pat. No. 7,676,045 to Merrey et al., entitled “Mountable Speaker Assembly” appears to disclose a speaker assembly, with clamps, and suspension ring that enable installation of the assembly in a ceiling tile. To secure the assembly to the ceiling, according to Merrey et al., the clamps are fixed to the housing using a fastener, such as a screw fastener, that penetrates the housing, wherein the rotation of the screw causes the clamp to move along an axis almost parallel with a center axis of the housing. This device thus requires use of tools to install and remove the mount.

As such, in view of the above, there is a need for a spring clip mounding system, including at least one spring clip and a mount, which enables electronics to be mounted on a wall without requiring the use of any tools.

### BRIEF SUMMARY OF THE INVENTION

One or more embodiments of the invention include a spring clip mounting system that enables electronics to be manually mounted in a cavity in a surface such as a wall, and manually removed from the wall, without requiring the use of any tools. In at least one embodiment, the spring clip mounting system includes at least one spring clip. In one or more embodiments, the at least one spring clip includes one or more of a body, a pin, a lever arm, a washer, a pole, a first spring element, a rectangle and a second spring element. The system enables rapid and easy installation of an electronics assembly by manually rotating the spring clip after the system is within a cavity and depressing a single component, namely a lever arm to move the body of the spring clip towards the inner portion of the cavity. The system enables rapid removal of the electronics assembly by manually asserting a single component, namely a “rectangle” and then rotating the spring clip to decrease the radial diameter of the system, which enables the system to be removed from the cavity.

According to at least one embodiment of the invention, the lever arm includes a distal end and a proximal end, wherein the lever arm is rotationally coupled with the body via the pin. In one or more embodiments, the washer may be coupled with a distal end of the lever arm. In at least one embodiment, the pole includes a top portion and an elongate rod, and is rotationally and moveably coupled to the body. In one or more embodiments, the first spring element is located above the washer on a first portion of the elongate rod.

By way of at least one embodiment of the invention, the rectangle includes at least one hole, a distal end and a proximal end. In one or more embodiments, the rectangle is located below the second spring element at a sloped angle relative to the body. In at least one embodiment, the rectangle is rotationally coupled to the body via the rectangle distal end and is slidingly coupled to the pole.

According to one or more embodiments, the second spring element is located below the washer and above the rectangle on a second portion of the elongate rod. In at least one embodiment, the body moves down the pole when a proximal portion of the lever arm is pushed down, which provides force on a portion of the washer and contacts the pole, which moves the body towards the second spring element, which provides force on a portion of the rectangle, and which loosens contact of the rectangle on the pole until the proximal portion of the lever arm is raised. As such, in at least one embodiment, an angled contact between the rectangle and the pole keeps the body at a lowered position.

In one or more embodiments, the body moves up the pole when a proximal portion of the rectangle is pushed up, which loosens contact of the rectangle with the pole, and which moves the body towards the first spring element until the proximal portion of the rectangle is lowered. As such, in at least one embodiment, the angled contact between the rectangle and the pole keeps the body at a raised position.

By way of one or more embodiments of the invention, the spring clip mounting system includes a mount, wherein the at least one spring clip is rotationally coupled with the mount via the pole, and is rotated to a first position to enable a portion of the mount and the at least one spring clip to be inserted into an opening in a wall. In at least one embodiment, the wall includes an inner portion and an outer portion. In one or more embodiments, the at least one spring clip is then rotated to a second position to enable the body of the at least one spring clip to be moved toward the inner portion of the wall to couple the mount to the wall when the lever arm is pushed down.

According to at least one embodiment, the rectangle is pushed up and the at least one spring clip is rotated in an opposite direction back to the first position to enable the portion of the mount and the at least one spring clip to be removed from the opening in the wall.

In one or more embodiments, the body includes a foot, such that the foot may contact the wall when the lever arm is pushed down to tighten the at least one spring clip on the wall. In at least one embodiment, the foot is released from the wall when the rectangle is pushed up to loosen the at least one spring clip from the wall.

According to at least one embodiment of the invention, the at least one spring clip includes one or more of a square located on top of the body, and a ring located on the top portion of the pole. In one or more embodiments, the square includes a hole, wherein the pole moves upward and downward through the hole of the square. In at least one embodiment, the ring located on the top portion of the pole may prevent the body from leaving the pole.

In one or more embodiments, the pole may include brass. In at least one embodiment, the body may include plastic. By way of one or more embodiments, the at least one spring clip may include a single spring clip coupled with the mount, or two spring clips coupled with the mount, or more than two spring clips coupled with the mount.

By way of at least one embodiment, the lever arm and the rectangle are sized to operate manually, wherein the lever arm is pushed down and the rectangle is pushed up manually, without requiring the use of any tools. In one or more embodiments of the invention, the spring clip mounting system may include electronics, wherein the electronics are coupled with the mount manually, without requiring the use of any tools.

### BRIEF DESCRIPTION OF THE DRAWINGS

The above and other aspects, features and advantages of at least one embodiment of the invention will be more apparent from the following more particular description thereof, presented in conjunction with the following drawings wherein:

FIG. 1 shows a first perspective view of at least one spring clip of a spring clip mounting system in a first orientation before coupling with an internal portion of a surface, according to at least one embodiment of the invention;

FIG. 2 shows a second perspective view of the at least one spring clip of the spring clip mounting system, in a second orientation as shown with the foot moved downward in the figure to engage an internal portion of a surface according to at least one embodiment of the invention;

FIG. 3 shows an exploded view of the at least one spring clip of the spring clip mounting system, according to at least one embodiment of the invention;

FIG. 4 shows a perspective view of the spring clip mounting system with a mount and a plurality spring clips, according to at least one embodiment of the invention with one of the spring clips in the raised position, ready to move downward;

FIG. 5 shows a side view of the spring clip mounting system with one spring clip, according to at least one embodiment of the invention;

FIG. 6 shows an exploded perspective view of the spring clip mounting system with the mount, a plurality of spring clips with one spring clip in the raised position, wherein the mount includes two portions that may be coupled without tools according to at least one embodiment of the invention;

FIG. 7 shows a left view of the at least one spring clip, according to at least one embodiment of the invention;

FIG. 8 shows a right view of the at least one spring clip, according to at least one embodiment of the invention

FIG. 9 shows a front view of the at least one spring clip, according to at least one embodiment of the invention

FIG. 10 shows a back view of the at least one spring clip, according to at least one embodiment of the invention;

FIG. 11 shows a top view of the at least one spring clip, according to at least one embodiment of the invention;

FIG. 12 shows a bottom view of the at least one spring clip, according to at least one embodiment of the invention;

FIG. 13 shows a cross-section of the at least one spring clip, according to at least one embodiment of the invention.

### DETAILED DESCRIPTION OF THE INVENTION

The following description is of the best mode presently contemplated for carrying out at least one embodiment of the invention. This description is not to be taken in a limiting sense, but is made merely for the purpose of describing the general principles of the invention. The scope of the invention should be determined with reference to the claims.

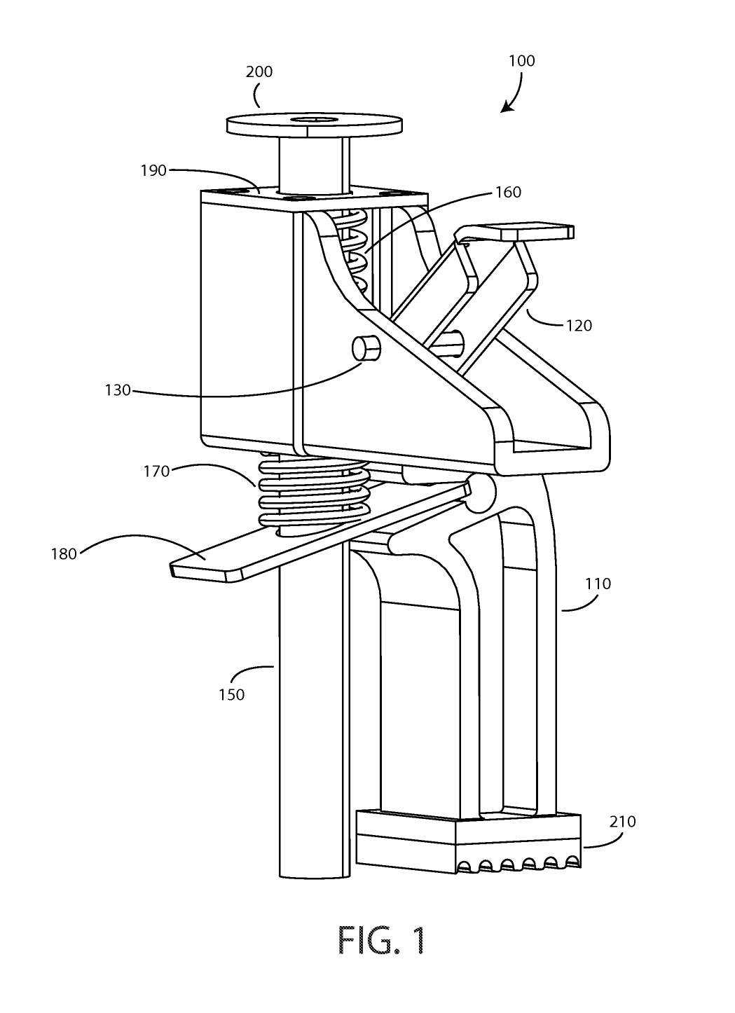

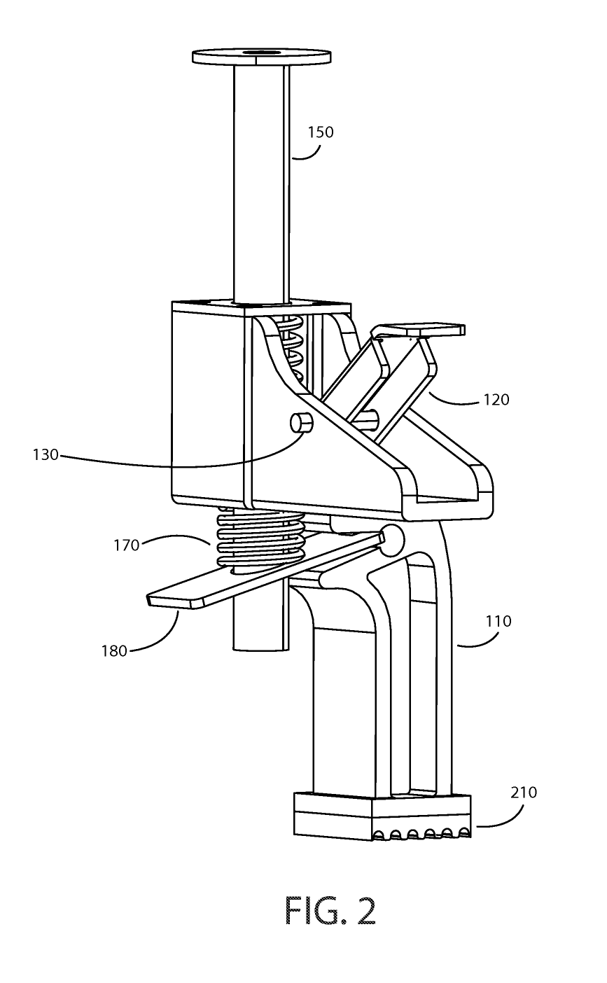

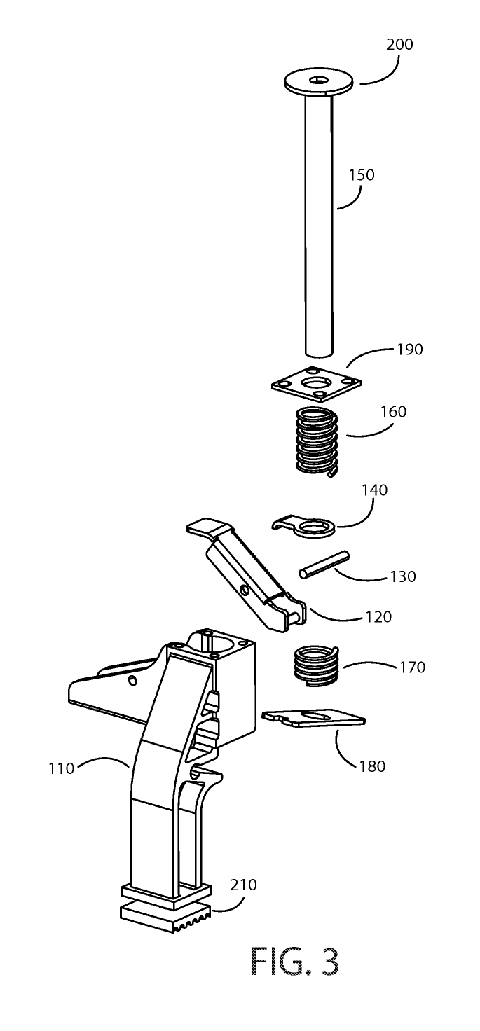

FIG. 1 shows a first perspective view of at least one spring clip of a spring clip mounting system in a first orientation before coupling with an internal portion of a surface, according to at least one embodiment of the invention. One or more embodiments of the invention include a spring clip mounting system that enables electronics to be installed or mounted on a wall, floor, ceiling or other surface manually, and removed from the wall manually, without requiring the use of any tools. In at least one embodiment, the spring clip mounting system includes at least one spring clip 100. FIG. 2 shows a second perspective view of the at least one spring clip of the spring clip mounting system, in a second orientation as shown with the foot moved downward in the figure to engage an internal portion of a surface according to at least one embodiment of the invention. FIG. 3 shows an exploded view of the at least one spring clip of the spring clip mounting system, according to at least one embodiment of the invention

As shown in FIGS. 1-3, in one or more embodiments, the at least one spring clip 100 includes one or more of a body 110, a lever arm 120, a pin 130, a washer 140, (see FIG. 3), a pole 150, a first spring element 160, a second spring element 170, and a rectangle 180.

According to at least one embodiment of the invention, the lever arm 120 includes a distal end and a proximal end, wherein the lever arm 120 is rotationally coupled with the body 110 via the pin 130. In one or more embodiments, the washer 140 may be coupled with a distal end of the lever arm 120. The washer is rotationally coupled to the pole and in one or more embodiments, surrounds the pole and provides a mechanism by which the lever moves the body down the pole via the lever arm. In at least one embodiment, the pole 150 includes a top portion and an elongate rod, and is rotationally and moveably coupled to the body 110. In one or more embodiments, the first spring element 160 is located above the washer 140 on a first portion of the elongate rod.

By way of at least one embodiment of the invention, the rectangle 180 includes at least one hole, a distal end and a proximal end. In one or more embodiments, the rectangle 180 is located below the second spring element 170 at a sloped angle relative to the body 110. In at least one embodiment, the rectangle 180 is rotationally coupled to the body 110 via the rectangle 180 distal end, and is slidingly coupled to the pole 150.

According to one or more embodiments, the second spring element 170 is located below the washer 140 and above the rectangle 180 on a second portion of the elongate rod of the pole 150. In at least one embodiment, the body 110 moves down the pole 150 when a proximal portion of the lever arm 120 is pushed down, which provides force on a portion of the washer 140 and contacts the pole 150, which moves the body 110 towards the second spring element 170, which provides force on a portion of the rectangle 180, and which loosens contact of the rectangle 180 on the pole 150 until the proximal portion of the lever arm 120 is raised. As such, in at least one embodiment, an angled contact between the rectangle 180 and the pole 150 keeps the body at a lowered position.

In one or more embodiments, the body 110 moves up the pole 150 when a proximal portion of the rectangle 180 is pushed up, which loosens contact of the rectangle 180 with the pole 150, and which moves the body 110 towards the first spring element 160 until the proximal portion of the rectangle 180 is lowered. As such, in at least one embodiment, the angled contact between the rectangle 180 and the pole 150 keeps the body 110 at a raised position.

As shown in FIG. 1 and FIG. 2, in one or more embodiments, the body 110 includes a foot 210, such that the foot 210 may contact the wall when the lever arm 120 is pushed down to tighten the at least one spring clip 100 on the wall. In one or more embodiments, the foot 210 may include one or more teeth that engage the wall. In at least one embodiment, the foot 210 is released from the wall when the rectangle 180 is pushed up to loosen the at least one spring clip 100 from the wall.

FIG. 3 shows an exploded view of the at least one spring clip of the spring clip mounting system, according to at least one embodiment of the invention. As shown in FIG. 3, the at least one spring clip 100 includes one or more of the body 110, the pin 130, the lever arm 120, the washer 140, which as shown provides a lip on the left as depicted that loosely couples with a horizontal rod depicted on the lower right of the lever arm, the pole 150, the first spring element 160, the rectangle 180 and the second spring element 170. According to at least one embodiment of the invention, the at least one spring clip 100 includes one or more of a square 190 located on top of the body 110, and a ring 200 located on the top portion of the pole 150. In one or more embodiments, the square 190 includes a hole, wherein the pole 150 moves upward and downward through the hole of the square 190. In at least one embodiment, the ring 200 located on the top portion of the pole 150 may prevent the body 110 from leaving the pole 150. One or more embodiments provide a step-less ratchet mechanism that enables rapid manual operation to couple and decouple the foot of the apparatus from an internal portion of the cavity in which the system is located.

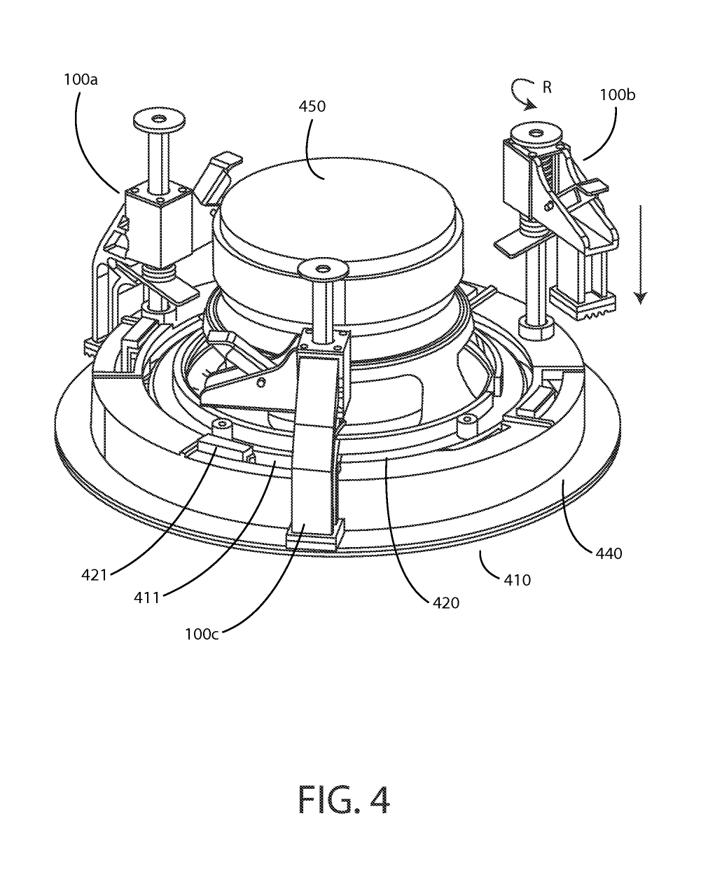

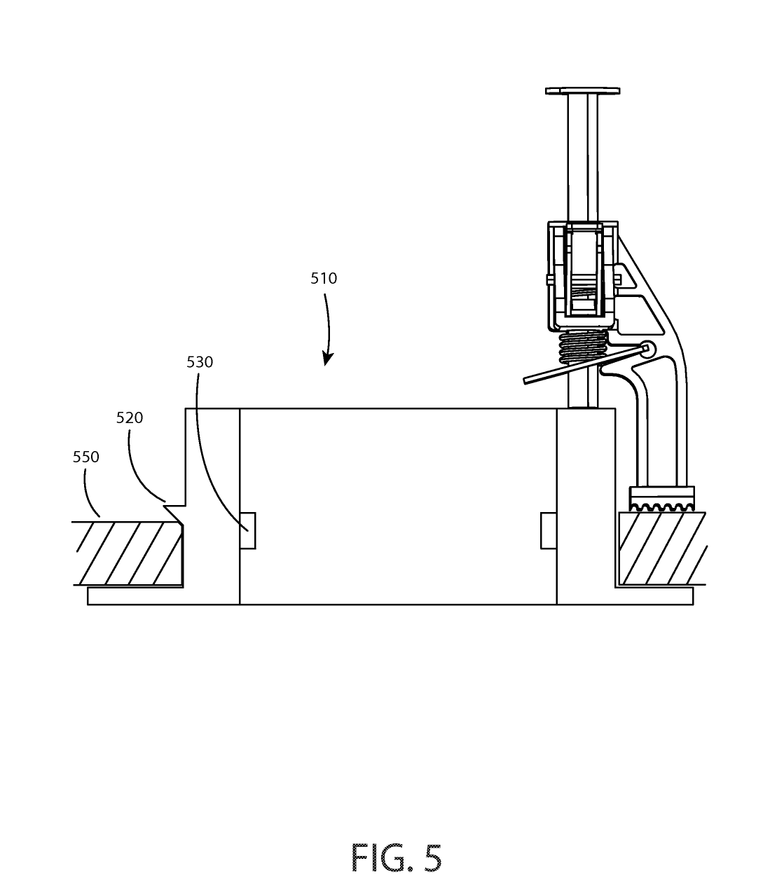

FIG. 4 shows a perspective view of the spring clip mounting system with a mount and a plurality of spring clips, according to at least one embodiment of the invention. As shown in FIG. 4, by way of one or more embodiments of the invention, the spring clip mounting system includes a mount 410, a mount flange 440 at a bottom portion of mount 410, and a plurality of spring clips 100a-c. The portion of the flange shown touches the outer portion of a cavity in which the system is installed while the foot of the at least one spring clip, when the body is rotated about the axis of the pole in direction R, contacts the inner portion of the cavity after the lever arm is asserted. Although three spring clips 100a-c are shown, in other embodiments, four or more may be utilized for larger electronics, or less than three may be utilized (see also FIG. 5). In at least one embodiment, at least one spring clip of the plurality of spring clips 100a-c are rotationally coupled with the mount 410, as described above and enabled by rotational couplings provided by the washer and rectangle. This enables the upper diameter of the system to be reduced by rotating the spring clips about their poles in the direction opposite of direction R. After the system is in the cavity, each of the at least one spring clips is then rotated in direction R to enable the feet to move downward (shown with a downward pointing arrow) against the inner surface of the cavity (shown as element 550 in FIG. 5). Specifically, the rotational coupling enables the body of each spring clip to move from an insertion orientation wherein the foot and lever arm are rotated clockwise from above to provide clearance for insertion into a insertion cavity in a surface where the system is to be mounted. Once inside the cavity the spring clips may be rotated counterclockwise to enable engagement of the feet on the body with the inside portion of the cavity on the surface as shown in FIG. 5 for example. Also shown are electronics sub-mount 420 and mount hole 411 and sub-mount tooth 421. The mount hole and tooth enable the mount and sub-mount, which holds the electronics 450 in one or more embodiments, to couple together without screws or bolts or other elements that require tools.

FIG. 5 shows a side view of the spring clip mounting system with one spring clip, according to at least one embodiment of the invention. As shown in FIG. 5, in one or more embodiments, the spring clip mounting system may include one spring clip mount 510. In at least one embodiment, the one spring clip mount 510 includes a wedge or snap mount 520 and electronics 530 that couple to a wall, such as a dry wall, 550. In one or more embodiments, the wedge or snap mount 520 is spring loaded, such that the one spring clip mount 510 wedges or snaps over the wall 550. In at least one embodiments, the one spring clip mount 510 includes a flange at a bottom portion of the spring clip mount 510, wherein the wedge or snap mount 520 sits on one side of the wall 550, and the flange sits at an opposing parallel side of the wall 550. As such, in one or more embodiments, the flange extends out from the bottom portion of the spring clip mount 510 to contact the wall 550 on one side while the wedge or snap mount 520 snaps over the wall 550 on the parallel opposing side of the wall 550. Thus, in one or more embodiments, a single spring clip may be utilized to install a mount without tools.

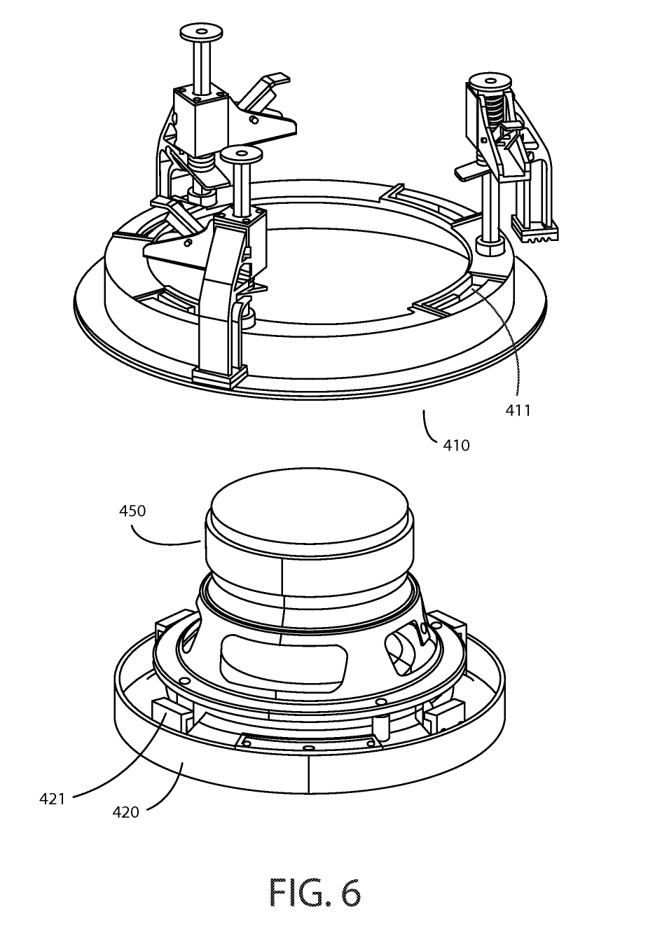

FIG. 6 shows an exploded perspective view of the spring clip mounting system with the mount, a plurality of spring clips and one spring clip in the raised position, wherein the mount includes two portions, e.g., mount 410 and sub-mount 420 that may be coupled without tools, according to at least one embodiment of the invention. As shown in FIG. 6, by way of one or more embodiments of the invention, the spring clip mounting system includes the mount 410, the plurality of spring clips 100a-c, the mount flange 440 at the bottom portion of the mount 410. In at least one embodiment, at least one spring clip of the spring clips 100a-c are rotationally coupled with the mount 410 via the pole 150, and is rotated to a first position to enable a portion of the mount 410 and the at least one spring clip of the spring clips 100a-c to be inserted into an opening in a wall as discussed above. In at least one embodiment, the wall includes an inner portion and an outer portion. In one or more embodiments, the at least one spring clip of the spring clips 100a-c are then rotated to a second position to enable the body 110 of at least one spring clip of the spring clips 100a-d to be moved toward the inner portion of the wall to couple the mount 410 to the wall when the lever arm 120 is pushed down. Once the mount is coupled with the cavity, then sub-mount 420 containing the electronics 450, may be connected to any wires and positioned within the inner area of mount 410 wherein teeth 421 of the sub-mount insert into the holes 411 of the mount and the sub-mount and electronics are then rotated so that the teeth no longer are oriented over holes 411, therein coupling the sub-mount and electronics to the mount without the use of tools.

According to at least one embodiment, the rectangle 180 is pushed up and the at least one spring clip 100 is rotated in an opposite direction back to the first position to enable the portion of the mount and the at least one spring clip 100 to be removed from the opening in the wall.

In one or more embodiments, the pole 150 may include brass. In at least one embodiment, the body 110 may include plastic, such as polyvinyl chloride (PVC). By way of one or more embodiments, the at least one spring clip 100 may include a single spring clip coupled with the mount, or two spring clips coupled with the mount, or more than two spring clips coupled with the mount. Any other types of materials may be utilized as desired and based on the particular installation in keeping with the spirit of the invention.

By way of at least one embodiment, the lever arm 120 and the rectangle 180 are sized to operate manually, wherein the lever arm 120 is pushed down manually to couple the spring clip mounting system to the wall, and the rectangle 180 is pushed up manually to decouple or remove the spring clip mounting system from the wall, without requiring the use of any tools. In one or more embodiments of the invention, the spring clip mounting system may include electronics, wherein the electronics are coupled with the mount manually, without requiring the use of any tools.

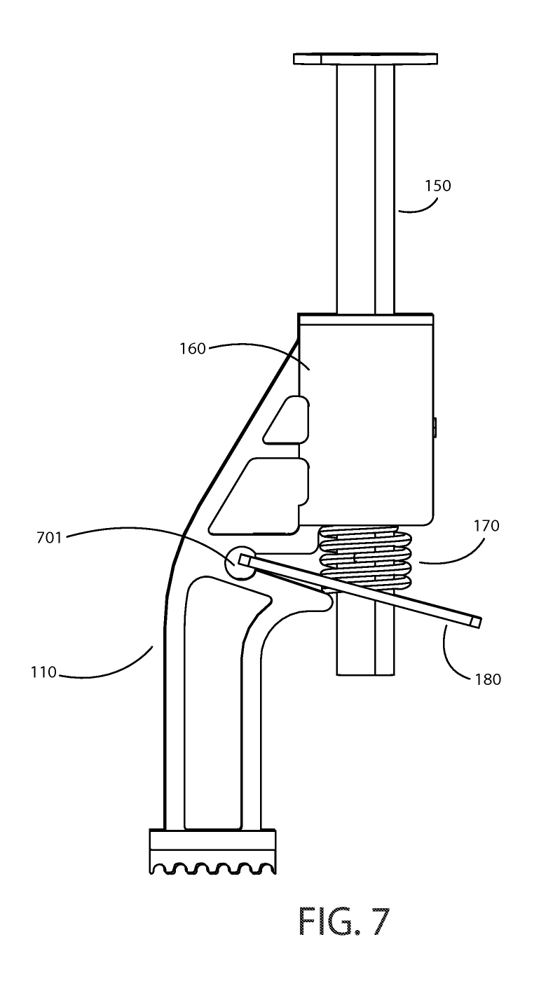

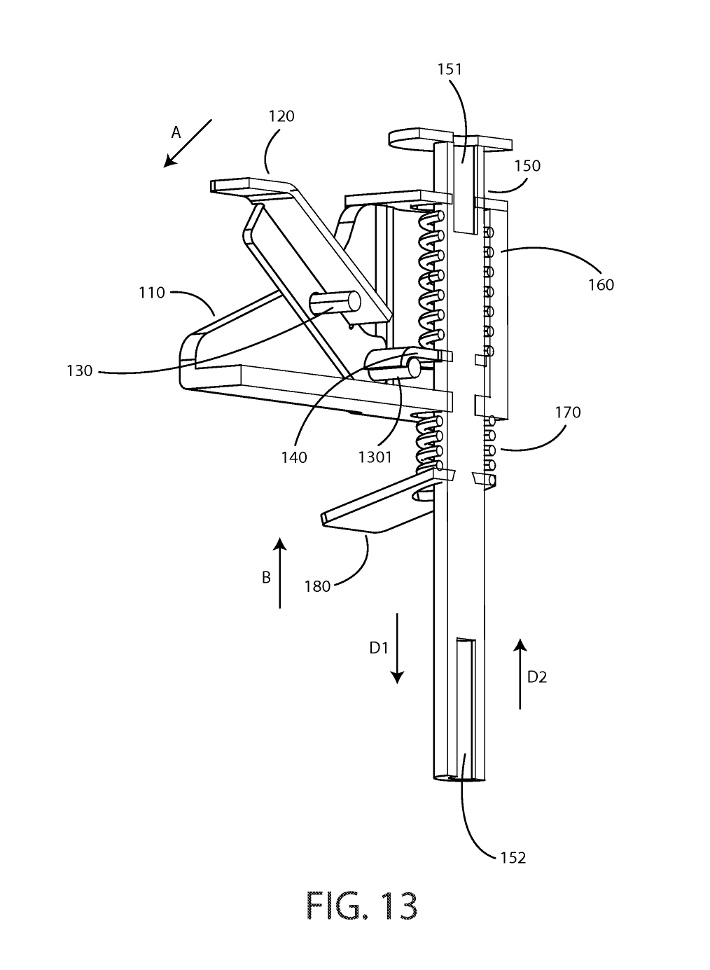

FIG. 7 shows a left view of the at least one spring clip, according to at least one embodiment of the invention. As shown in FIG. 7, in one or more embodiments, the at least one spring clip 100 includes the body 110, the pole 150, the first spring element 160, the second spring element 170 and the rectangle 180. In at least one embodiment, the pole 150 may be threaded and include a first threaded hole 151 on the first portion of the elongate rod, and a second threaded hole 152 on the second portion of the elongate rod (see FIG. 13). The threaded holes enable mounting of the retainer or ring on the top of the pole and enable mounting of the pole to mount 410 (see FIG. 4). Rectangle 180 is shown coupled to body 110 via pivot 701. Spring 170 thus presses rectangle 180 at an angle to pole 150, which provide friction and a step-less ratchet coupling effectively between body 110 and pole 150.

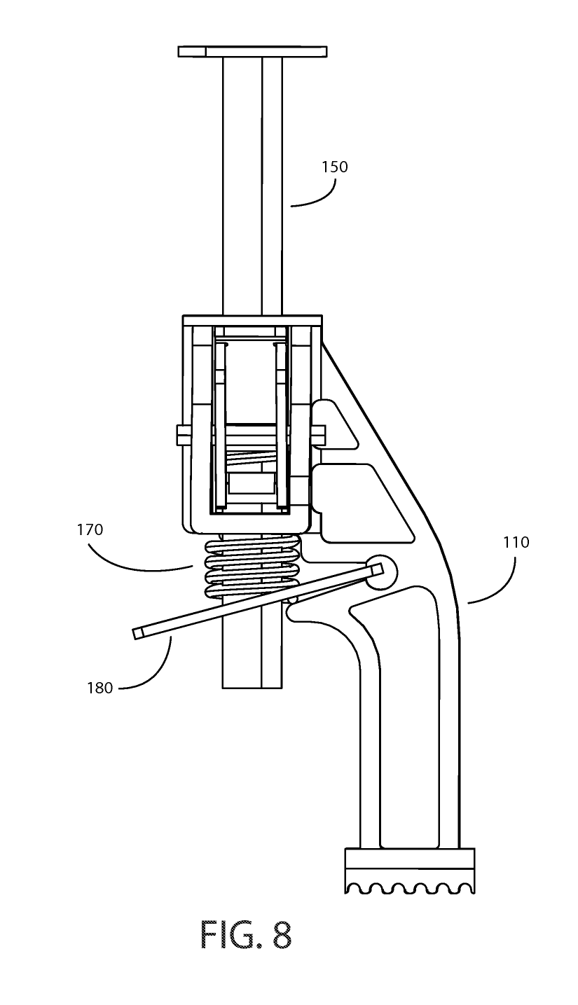

FIG. 8 shows a right view of the at least one spring clip, according to at least one embodiment of the invention. As shown in FIG. 8, in one or more embodiments, the at least one spring clip 100 includes the body 110, the pole 150, the second spring element 170 and the rectangle 180.

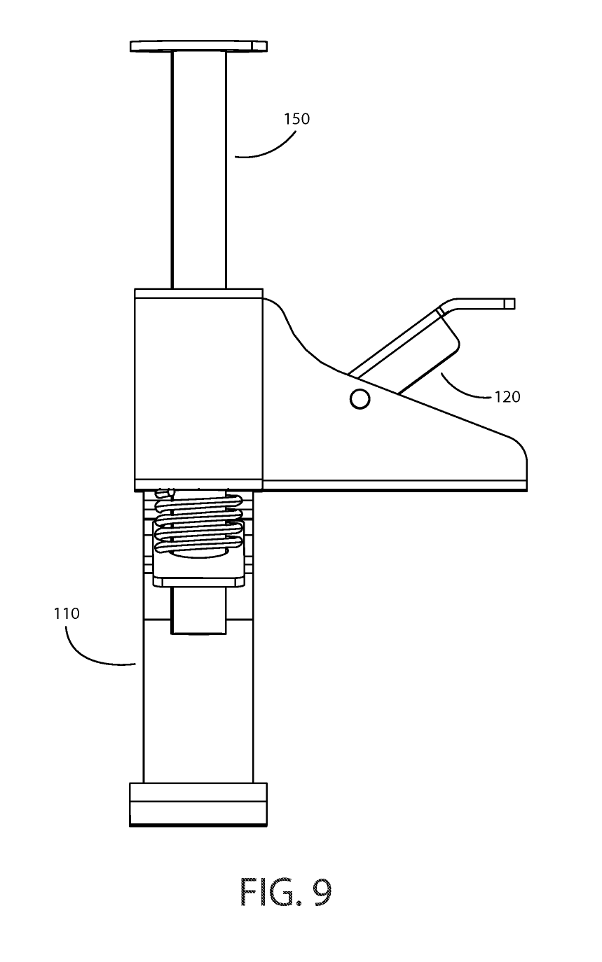

FIG. 9 shows a front view of the at least one spring clip, according to at least one embodiment of the invention. As shown in FIG. 9, in one or more embodiments, the at least one spring clip 100 includes the body 110, the pole 150, the lever arm 120.

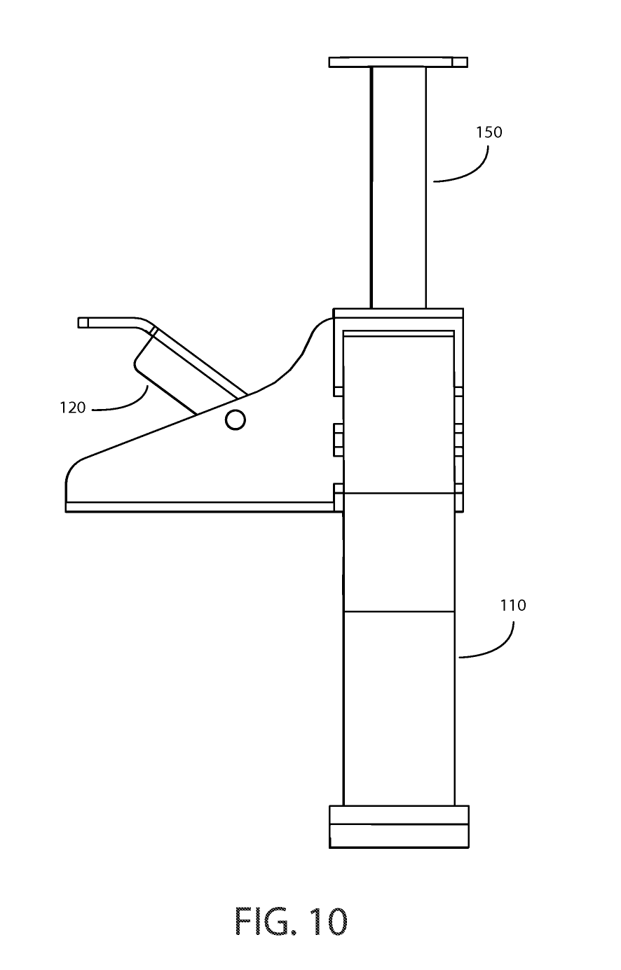

FIG. 10 shows a back view of the at least one spring clip, according to at least one embodiment of the invention. As shown in FIG. 10, in one or more embodiments, the at least one spring clip 100 includes the body 110, the pole 150, the lever arm 120.

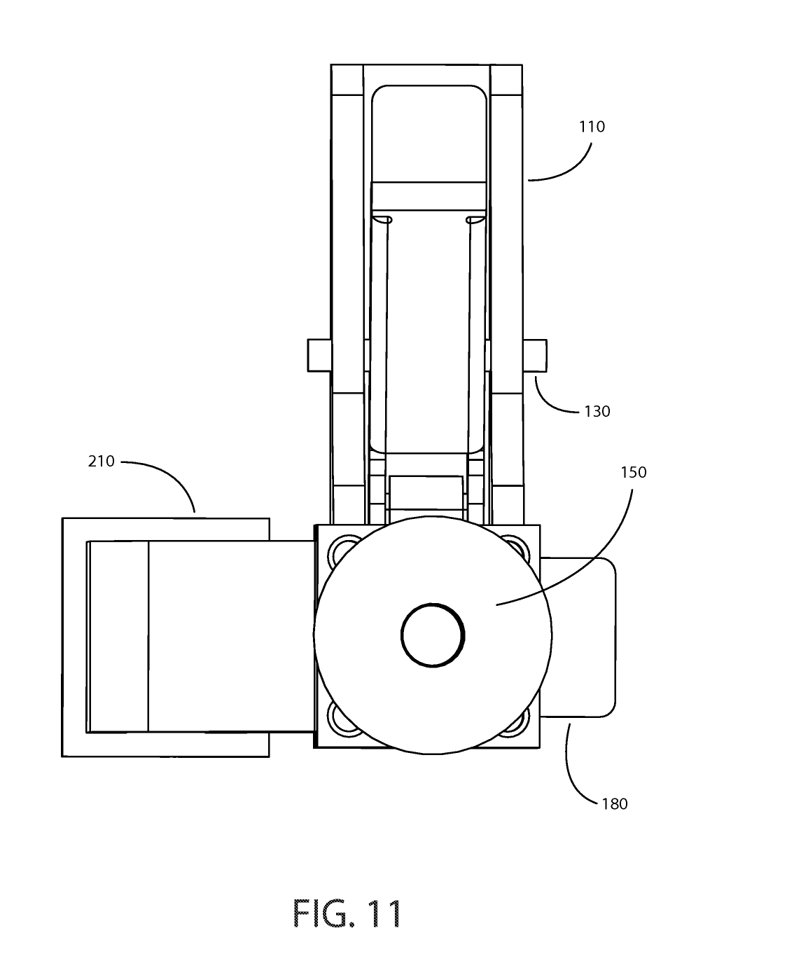

FIG. 11 shows a top view of the at least one spring clip, according to at least one embodiment of the invention. As shown in FIG. 11, the at least one spring clip includes the body 110, the pin 130, the pole 150, the rectangle 180 and the foot 210. If the bottom of the device as oriented in FIG. 11 is aligned within the ledge of mount 410, e.g., that leads down to mount flange 440, and then rotated about the axis defined by pole 150, (for example as shown rotating through direction R as shown in FIG. 4), then foot 210 is thus positioned over the flange and may then be extended downward when the lever arm 120 (see FIG. 10) is asserted to couple with the inner portion of a cavity in which the device is situated wherein the mount flange 440 lies on the outer portion of the cavity to hold the system in place between the foot and the flange. This is also shown in FIG. 5, i.e., after rotation of the body so that the lever arm is somewhat in line with the rim of the mount and the foot is over the flange, wherein during installation, the foot is over the rim of the mount and there are no parts that extend in a radial direction further out from the rim, e.g., do not extend over the flange, so that the mount may be inserted into the cavity.

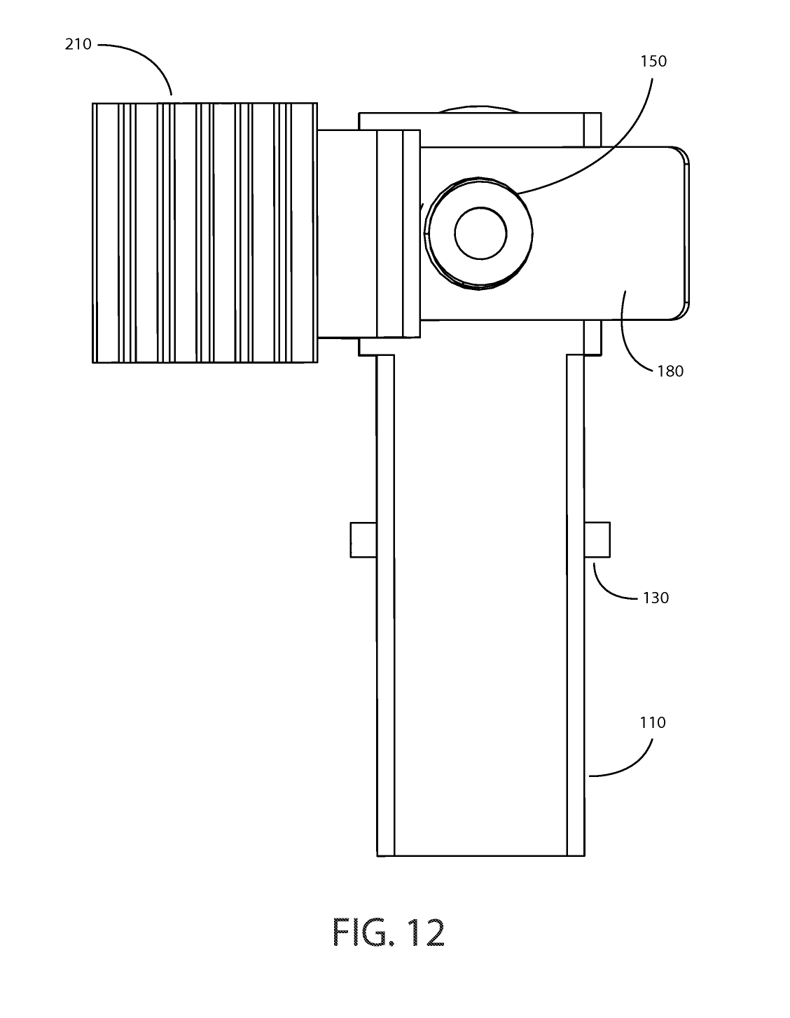

FIG. 12 shows a bottom view of the at least one spring clip, according to at least one embodiment of the invention. As shown in FIG. 12, in one or more embodiments, the at least one spring clip 100 includes the body 110, the pole 150, the pin 130, the rectangle 180, and the foot 210.

FIG. 13 shows a cross-section of the at least one spring clip, according to at least one embodiment of the invention. As shown in FIG. 13, the at least one spring clip includes the lever arm 120 rotationally coupled to the pole 150 via washer 140, the first spring element 160, the second spring element 170 and the rectangle 180. In at least one embodiment, the pole 150 may be threaded and include the first threaded hole 151 on the first portion of the elongate rod, and a second threaded hole 152 on the second portion of the elongate rod. In one or more embodiments, the first threaded hole 151 on the first portion of the elongate rod enables coupling of the ring to the top portion of the pole 150. In at least one embodiment, the second threaded hole 152 is located on the second portion of the elongate rod extends through a bottom outer edge of the pole 150 and enables coupling of the pole and therefore spring clip to mount 410. In other embodiments, holes 151 and 152 are not required and the top end of the pole may be larger than the diameter of the hole on the top of the body to prevent the body from escaping the pole when moved upward. Any attachment mechanism, for example a flange may be utilized on the bottom of the pole to couple the pole to the mount in keeping with the spirit of the invention. Embodiments of the invention operate to move body 110 in direction D1 when lever arm 120 is moved in direction A, which pushes up on the left portion of washer 140, shown as a lip that loosely couples with horizontal rod 1301 on lever arm 120. This movement provides downward force on body 110 via pin 130. When lever arm 120 is released, e.g., in the opposite direction of direction A, then spring 160 pushes the washer down pole 150. For removal, rectangle 180 is asserted in direction B, which levels rectangle 180 that is pressed at an angle on pole 150 (see also FIG. 7), which enables body 110 to move in direction D2 to disengage the body from an internal portion of the cavity in which the assembly is mounted.

It will be apparent to those skilled in the art that numerous modifications and variations of the described examples and embodiments are possible in light of the above teaching. The disclosed examples and embodiments are presented for purposes of illustration only. Other alternate embodiments may include some or all of the features disclosed herein. Therefore, it is the intent to cover all such modifications and alternate embodiments as may come within the true scope of this invention.

What is claimed is:

1. A spring clip mounting system that enables electronics to be mounted on a wall comprising:
at least one spring clip, wherein said at least one spring clip comprises
a body;
a pin;
a lever arm having a distal and proximal end wherein said lever arm is rotationally coupled with said body via said pin;
a washer coupled with a distal end of said lever arm;
a pole rotationally and moveably coupled to said body, wherein said pole comprises a top portion and an elongate rod;
a first spring element located above said washer on a first portion of said elongate rod;
a rectangle having a hole wherein said rectangle comprises a distal and proximal end located below said second spring element at a sloped angle relative to said body, wherein said rectangle is rotationally coupled to said body via said distal end and slidingly coupled to said pole;
a second spring element located below said washer and above said rectangle on a second portion of said elongate rod;
wherein said body moves down said pole when a proximal portion of said lever arm is pushed down, which provides force on a portion of the washer and contacts the pole, which moves the body towards the second spring element, which provides force on a portion of the rectangle, which loosens contact of the rectangle on the pole until said proximal portion of said lever arm is raised wherein an angled contact between said rectangle and said pole keeps said body at a lowered position, and
wherein said body moves up said pole when a proximal portion of said rectangle is pushed up, which loosens contact of the rectangle with the pole, which moves the body towards the first spring element until said proximal portion of said rectangle is lowered wherein said angled contact between said rectangle and said pole keeps said body at a raised position.

2. The spring clip mounting system of claim 1, further comprising a mount wherein said at least one spring clip is rotationally coupled with said mount via said pole and rotated to a first position to enable a portion of said mount and said at least one spring clip to be inserted into an opening in a wall, wherein the wall comprises an inner portion and an outer portion, and wherein the at least one spring clip is then rotated to a second position to enable said body of at least one spring clip to be moved toward the inner portion of the wall to couple said mount to said wall when said lever arm is pushed down.

3. The spring clip mounting system of claim 2, wherein said rectangle is pushed up and said at least one spring clip is rotated in an opposite direction back to said first position to enable said portion of said mount and said at least one spring clip to be removed from said opening in said wall.

4. The spring clip mounting system of claim 2, wherein said body comprises a foot, such that said foot contacts said wall when said lever arm is pushed down to tighten said at least one spring clip on said wall and wherein said foot is released from said wall when said rectangle is pushed up to loosen said at least one spring clip from said wall.

5. The spring clip mounting system of claim 1, wherein said at least one spring clip further comprises a square located on top of said body comprising a hole, wherein said pole moves upward and downward through said hole.

6. The spring clip mounting system of claim 1, wherein said at least one spring element further comprises a ring located on said top portion of said pole to prevent said body from leaving said pole.

7. The spring clip mounting system of claim 1, wherein said pole comprises brass.

8. The spring clip mounting system of claim 1, wherein said body comprises plastic.

9. The spring clip mounting system of claim 2, wherein said at least one spring clip further comprises a single spring clip coupled with said mount.

10. The spring clip mounting system of claim 2, wherein said at least one spring clip further comprises two spring clips coupled with said mount.

11. The spring clip mounting system of claim 2, wherein said at least one spring clip further comprises more than two spring clips coupled with said mount.

12. The spring clip mounting system of claim 1, wherein said lever arm and said rectangle are sized to operate manually, wherein said lever arm is pushed down and said rectangle is pushed up manually.

13. The spring clip of mounting system of claim 1, further comprising electronics, wherein said electronics are coupled with said mount manually.

14. A spring clip mounting system that enables electronics to be mounted on a wall comprising:
at least one spring clip, wherein said at least one spring clip comprises
a body;
a pin;
a lever arm having a distal and proximal end wherein said lever arm is rotationally coupled with said body via said pin;
a washer coupled with a distal end of said lever arm;
a pole rotationally and moveably coupled to said body, wherein said pole comprises a top portion and an elongate rod;
a first spring element located above said washer on a first portion of said elongate rod;
a rectangle having a hole wherein said rectangle comprises a distal and proximal end located below said second spring element at a sloped angle relative to said body, wherein said rectangle is rotationally coupled to said body via said distal end and slidingly coupled to said pole;
a second spring element located below said washer and above said rectangle on a second portion of said elongate rod;
wherein said body moves down said pole when a proximal portion of said lever arm is pushed down, which provides force on a portion of the washer and contacts the pole, which moves the body towards the second spring element, which provides force on a portion of the rectangle, which loosens contact of the rectangle on the pole until said proximal portion of said lever arm is raised wherein an angled contact between said rectangle and said pole keeps said body at a lowered position, and
wherein said body moves up said pole when a proximal portion of said rectangle is pushed up, which loosens contact of the rectangle with the pole, which moves the body towards the first spring element until said proximal portion of said rectangle is lowered wherein said angled contact between said rectangle and said pole keeps said body at a raised position;
a mount;
wherein said at least one spring clip is rotationally coupled with said mount via said pole and rotated to a first position to enable a portion of said mount and said at least one spring clip to be inserted into an opening in a wall, wherein the wall comprises an inner portion and an outer portion, and wherein the at least one spring clip is then rotated to a second position to enable said body of at least one spring clip to be moved toward the inner portion of the wall to couple said mount to said wall when said lever arm is pushed down, and,
wherein said rectangle is pushed up and said at least one spring clip is rotated in an opposite direction back to said first position to enable said portion of said mount and said at least one spring clip to be removed from said opening in said wall; and,
wherein said body comprises a foot, such that said foot contacts said wall when said lever arm is pushed down to tighten said at least one spring clip on said wall and wherein said foot is released from said wall when said rectangle is pushed up to loosen said at least one spring clip from said wall.

15. A spring clip mounting system that enables electronics to be mounted on a wall comprising:
at least one spring clip, wherein said at least one spring clip comprises
a body;
a pin;
a lever arm having a distal and proximal end wherein said lever arm is rotationally coupled with said body via said pin;
a washer coupled with a distal end of said lever arm;
a pole rotationally and moveably coupled to said body, wherein said pole comprises a top portion and an elongate rod;
a first spring element located above said washer on a first portion of said elongate rod;
a rectangle having a hole wherein said rectangle comprises a distal and proximal end located below said second spring element at a sloped angle relative to said body, wherein said rectangle is rotationally coupled to said body via said distal end and slidingly coupled to said pole;
a second spring element located below said washer and above said rectangle on a second portion of said elongate rod;
wherein said body moves down said pole when a proximal portion of said lever arm is pushed down, which provides force on a portion of the washer and contacts the pole, which moves the body towards the second spring element, which provides force on a portion of the rectangle, which loosens contact of the rectangle on the pole until said proximal portion of said lever arm is raised wherein an angled contact between said rectangle and said pole keeps said body at a lowered position, and
wherein said body moves up said pole when a proximal portion of said rectangle is pushed up, which loosens contact of the rectangle with the pole, which moves the body towards the first spring element until said proximal portion of said rectangle is lowered wherein said angled contact between said rectangle and said pole keeps said body at a raised position;
a square located on top of said body comprising a hole, wherein said pole moves upward and downward through said hole; and,
a ring located on said top portion of said pole to prevent said body from leaving said pole;
a mount;
wherein said at least one spring clip is rotationally coupled with said mount via said pole and rotated to a first position to enable a portion of said mount and said at least one spring clip to be inserted into an opening in a wall, wherein the wall comprises an inner portion and an outer portion, and wherein the at least one spring clip is then rotated to a second position to enable said body of at least one spring clip to be moved toward the inner portion of the wall to couple said mount to said wall when said lever arm is pushed down, and,
wherein said rectangle is pushed up and said at least one spring clip is rotated in an opposite direction back to said first position to enable said portion of said mount and said at least one spring clip to be removed from said opening in said wall; and,
wherein said body comprises a foot, such that said foot contacts said wall when said lever arm is pushed down to tighten said at least one spring clip on said wall and wherein said foot is released from said wall when said rectangle is pushed up to loosen said at least one spring clip from said wall.
